(19) United States
(12) Patent Application Publication
(10) Pub. No.: US 2026/0092749 A1
(43) Pub. Date: Apr. 2, 2026

(54) LIQUID COOLING AUTOMATED DISCONNECT COMPONENT

(71) Applicant: DELL PRODUCTS L.P., Round Rock, TX (US)

(72) Inventors: Kevin Mundt, Livingston, TX (US); Sandor Farkas, Round Rock, TX (US)

(21) Appl. No.: 18/898,949

(22) Filed: Sep. 27, 2024

(51) Int. Cl. F28F 9/02; H05K 7/20

(52) U.S. Cl. CPC F28F 9/0258; F28F 2265/16; H05K 7/20763; H05K 7/20836

(57) ABSTRACT

A quick disconnect component includes a disconnect and a motor assembly. The disconnect includes a manifold portion and a hose portion. The motor assembly is coupled to the disconnect and includes a motor. In response to a leak indication, the motor pulls the manifold portion towards the hose portion. When the manifold portion is in physical communication with the hose portion, the disconnect automatically detaches from a manifold of a liquid cooling system in an information handling system.

### FIELD OF THE DISCLOSURE

The present disclosure generally relates to information handling systems, and more particularly relates to a liquid cooling automated disconnect component.

### BACKGROUND

As the value and use of information continues to increase, individuals and businesses seek additional ways to process and store information. One option is an information handling system. An information handling system generally processes, compiles, stores, or communicates information or data for business, personal, or other purposes. Technology and information handling needs and requirements can vary between different applications. Thus information handling systems can also vary regarding what information is handled, how the information is handled, how much information is processed, stored, or communicated, and how quickly and efficiently the information can be processed, stored, or communicated. The variations in information handling systems allow information handling systems to be general or configured for a specific user or specific use such as financial transaction processing, airline reservations, enterprise data storage, or global communications. In addition, information handling systems can include a variety of hardware and software resources that can be configured to process, store, and communicate information and can include one or more computer systems, graphics interface systems, data storage systems, networking systems, and mobile communication systems. Information handling systems can also implement various virtualized architectures. Data and voice communications among information handling systems may be via networks that are wired, wireless, or some combination.

### SUMMARY

A quick disconnect component includes a disconnect and a motor assembly. The disconnect includes a manifold portion and a hose portion. The motor assembly is coupled to the disconnect and includes a motor. In response to a leak indication, the motor may pull the manifold portion towards the hose portion. When the manifold portion is in physical communication with the hose portion, the disconnect may automatically detach from a manifold of a liquid cooling system in an information handling system.

### BRIEF DESCRIPTION OF THE DRAWINGS

It will be appreciated that for simplicity and clarity of illustration, elements illustrated in the Figures are not necessarily drawn to scale. For example, the dimensions of some elements may be exaggerated relative to other elements. Embodiments incorporating teachings of the present disclosure are shown and described with respect to the drawings herein, in which:

FIG. 1 is a block diagram of a system including multiple information handling systems according to at least one embodiment of the present disclosure;

FIG. 2 is a perspective view of a quick disconnect component according to at least one embodiment of the present disclosure;

FIG. 3 is an exploded perspective view of a motor assembly for a quick disconnect component according to at least one embodiment of the present disclosure;

FIG. 4 is a cross-sectional view of a quick disconnect component according to at least one embodiment of the present disclosure;

FIG. 5-7 are different exploded perspective views of a quick disconnect component according to at least one embodiment of the present disclosure;

FIG. 8 is a flow diagram of a method for determining a status of a quick disconnect component according to at least one embodiment of the present disclosure; and

FIG. 9 is a block diagram of a general information handling system according to at least one embodiment of the present disclosure.

The use of the same reference symbols in different drawings indicates similar or identical items.

### DETAILED DESCRIPTION OF THE DRAWINGS

The following description in combination with the Figures is provided to assist in understanding the teachings disclosed herein. The description is focused on specific implementations and embodiments of the teachings, and is provided to assist in describing the teachings. This focus should not be interpreted as a limitation on the scope or applicability of the teachings.

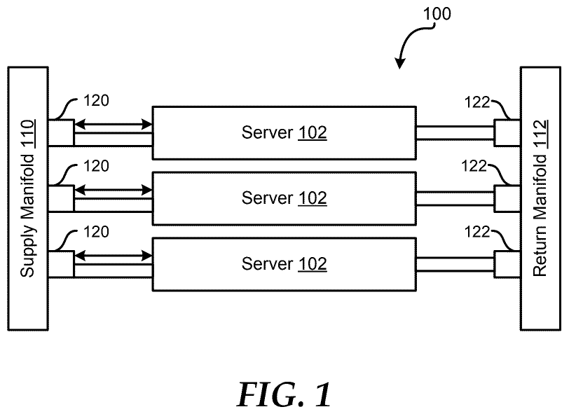

FIG. 1 illustrates a system 100 including multiple information handling systems 102 according to at least one embodiment of the present disclosure. For purposes of this disclosure, an information handling system may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, an information handling system may be a personal computer, a PDA, a consumer electronic device, a network server or storage device, a switch router or other network communication device, or any other suitable device and may vary in size, shape, performance, functionality, and price. The information handling system may include memory, one or more processing resources such as a central processing unit (CPU) or hardware or software control logic. Additional components of the information handling system may include one or more storage devices, one or more communications ports for communicating with external devices as well as various other I/O devices, such as a keyboard, a mouse, and a video display. The information handling system may also include one or more busses operable to transmit communications between the various hardware components.

System 100 further includes a supply manifold 110, a return manifold 112, multiple quick disconnect components 120, and multiple return side connectors 122. System 100 may be any suitable system, such as an information handling system or server rack. Supply manifold 110 may provide cold cooling liquid to each information handling system or server 102 in the larger information handling system or server rack. Return manifold 112 may receive hot cooling liquid from each information handling system or server 102 in the larger information handling system or server rack. A different one of quick disconnect components 120 may be connected between supply manifold 110 and a different liquid cooling supply line. Similarly, a different one of return side connectors 122 may be connected between return manifold 112 and a different liquid cooling return line. In certain examples, a different one of quick disconnect components 120 may be electrically coupled to a different corresponding server 102. System 100 may include additional components without varying from the scope of this disclosure.

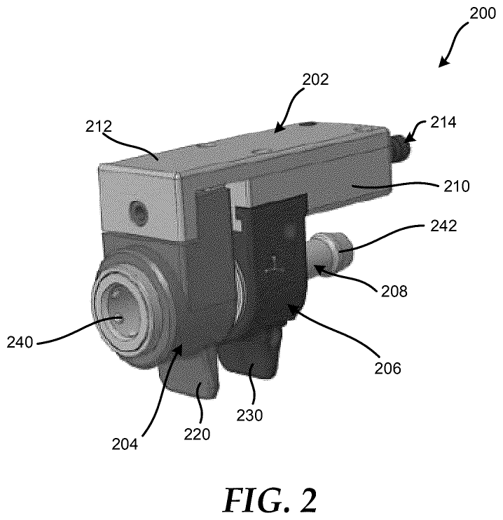

In an example, supply manifold 110, return manifold 112, multiple quick disconnect components 120, and multiple return side connectors 122 may form a portion of a direct liquid cooling for information handling systems or servers 102. The direct liquid cooling system may also include one or more cold plates in each of the servers 102, a main supply liquid system connected to supply manifold 110, and a main return liquid line connected to return manifold 112. In different embodiments, return side connectors 122 may be quick disconnect components, such as quick disconnect component 200 of FIG. 2, may be check valves, or a combination of quick disconnect components and check values.

In certain situations, a leak may occur at one or more of the components of the liquid cooling system within system 100, which may cause damage to information handling systems 102. In an example, both supply manifold 120 and return manifold 122 are pressurized, such that if the flow of cooling liquid is not stopped the pressurized cooling liquid may continue to flow at the source of the leak. For example, a leak in a cooling loop of server 102 would be fed from both the cold line of supply manifold 110 and the hot return line connected to return manifold 112. Thus, both connections to supply and return manifolds 110 and 112 need to be isolated.

Quick disconnect components 120 and return line connectors 122 may be utilized to mitigate a leak within system 100. For example, in response to a detected leak, quick disconnect components 120 and return line connectors 122 may shut of the flow of cooling liquid to server 102 in which the leak was detected. In this example, quick disconnect components 120 may stop the flow of cooling liquid from supply manifold 110 and return line connectors 122 may prevent a backflow of cooling liquid from return manifold 112.

In an example, return side connector 122 may be a check valve and may be placed in line between the return hose and return manifold 112. The check valve allows for flow in only one direction and may be oriented so that the cooling liquid may flow to hot return manifold 112 but can't backflow in the case of a leak. When a leak is detected, server 102 may assert quick disconnect component 120 and the flow will cease from cold supply manifold 110. The check valve 122 may prevent backflow from hot return manifold 122. Based on these operations, the server cooling loop is now isolated from the pressure of both manifolds 120 and 122.

FIG. 2 illustrates a quick disconnect component 200 according to at least one embodiment of the present disclosure. Quick disconnect component 200 may be substantially similar to quick disconnect components 120 of FIG. 1. Quick disconnect component 200 includes a motor assembly 202, collars 204 and 206, and a disconnect 208. Motor assembly 202 includes a motor housing 210, a cover 212, and a wire connector 214. Collar 204 includes a manual tab 220, and collar 206 includes a manual tab 230. Disconnect 208 includes a manifold portion 240 and a hose portion 242. Quick disconnect component 200 may include additional sub-components without varying from the scope of this disclosure.

As illustrated in FIG. 2, collars 204 and 206 may physically couple disconnect 208 to motor assembly 202. In particular, collar 204 may couple manifold portion 240 of disconnect 208 to cover 212 and collar 230 may couple hose portion 242 to motor housing 210. As will be described in detail below, collars 204 and 206 may be utilized to enable the quick disconnect between manifold portion 240 and hose portion 242 to stop the flow of cooling liquid when a leak is detected.

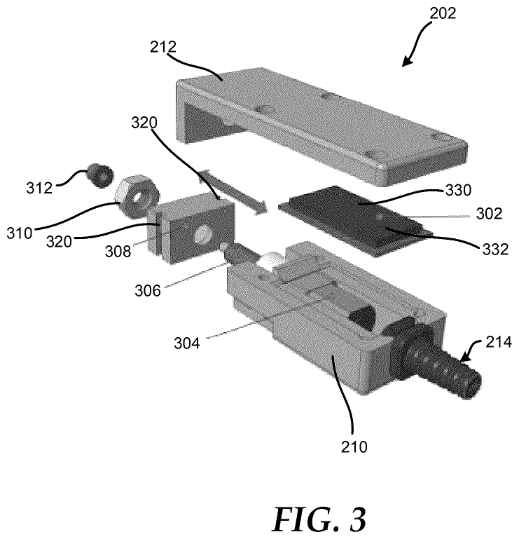

FIG. 3 illustrates motor assembly 202 for quick disconnect component 200 of FIG. 2 according to at least one embodiment of the present disclosure. Motor assembly 202 includes a controller printed circuit board (PCB) 302, a motor 304, a threaded shaft 306, a block 308, a nut 310, a bushing 312, motor housing 210, cover 212, and wire connector 214. Controller PCB 302 includes a processor 330 and an H-bridge 332 with current sense. Block 308 includes channels 320, which in turn may be physically coupled to collar 204 as will be described in more detail below. Motor assembly 202 may include additional components without varying from the scope of this disclosure.

In an example, one or more wires may be inserted within motor housing 210 through wire connector 214. The wires may include communication wires and power wires. The power wires may electrically connect with controller PCB 302 and with motor 304. The communication wires may electrically connect with controller PCB 302. Additionally, controller PCB 302 may be electrically coupled to motor 304, which in turn may enable processor and H-bridge to control and receive feedback from the motor.

In certain examples, threaded shaft may be in physical communication with motor 304 and may be slid through an opening in block 308. Nut 310 may be screwed onto threaded shaft 306 and bushing 312 may be mounted on an end of the threaded shaft. Bushing 312 may support the rotation of threaded shaft 306. In an example, bushing 312 may prevent nut 310 from coming off of threaded shaft 306. Nut 310 may be biased in physical communication with a portion of block 308, which in turn may prevent the nut from rotating while the threaded shaft 306 is rotated by motor 304. When motor 304 rotates threaded shaft 306 in one direction, nut 310 may be drawn towards the motor. While nut 310 is drawn towards motor 304, the nut may exert a force on block 308 and this force may cause block 308 to translate toward the motor and motor housing 210.

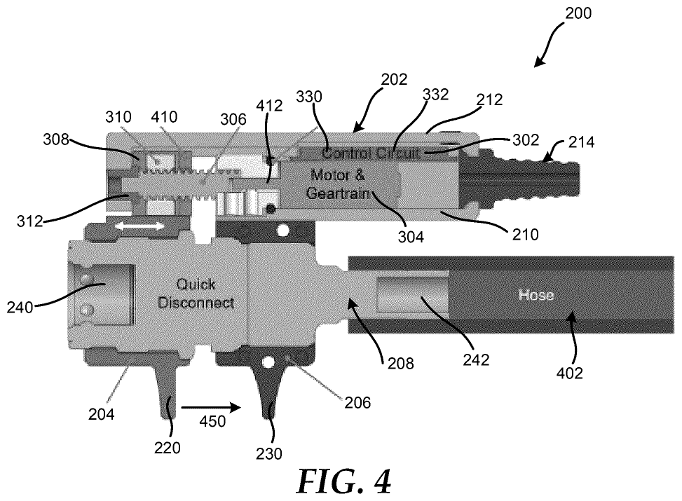

FIG. 4 illustrates a cross-section of quick disconnect component 200 according to at least one embodiment of the present disclosure. Hose portion 242 may be attached to a hose 402. Block 410 includes a wall 410, and motor 304 includes a drive shaft 412. Collars 204 206 may secure disconnect mechanism 208 to motor assembly 202. In particular, collar 204 may securely couple manifold portion 240 to block 308 and collar 206 may couple cooling line connector 242 to motor housing 210. In certain examples, different types disconnects 208 may be different sizes, such that different collars 204 and 206 may need to be used to hold different disconnects 208 to motor assembly 202. In these situations, the sizes of collars 204 and 206 may be selected based on the size of disconnect 208. Quick disconnect component 200 may include additional sub-components without varying from the scope of this disclosure.

In an example, wall 410 of block 308 is located on a single side of nut 310, such as the side nearest motor 304. Based on the location of wall 410, a user may utilize manual tabs 220 and 230 to manually release quick disconnect component 200 from supply manifold 110 of FIG. 1. In certain examples, the location of collar 206 may be fixed with respect to motor housing 210, such that collar 206 and the portion of disconnect 208 does not move or translate during operation of quick disconnect component 200. However, block 308 and collar 204 may move or translate without nut 310 moving. For example, collar 204 may move manifold portion 240 toward collar 230 in the direction of arrow 450. As collar 204 and manifold portion 240 move or translate a predetermined distance, the manifold portion may disconnect from a manifold, such as supply manifold 110 of FIG. 1.

Based on the ability of block 310 and collar 204 to move, a user may squeeze tabs 220 and 230 together to release disconnect 208 from a liquid cooling manifold, such as supply manifold 110 of FIG. 1. For example, as the user squeezes tabs 220 and 230 together collar 204 may move manifold portion 240 toward collar 230 in the direction of arrow 450. As collar 204 and manifold portion 240 move or translate a predetermined distance, the manifold portion may disconnect from a manifold, such as supply manifold 110 of FIG. 1.

In an example, motor 304 may be any suitable dual direction motor, such as a direct current (DC) gearmotor, and the motor may be coupled to threaded shaft 306 via drive shaft 412. During the automated operation of quick disconnect component 200, motor 304 may draw or pull nut 310 on threaded shaft 306 towards collar 206 until collar 204 is placed in physical communication with collar 206. After collars 204 and 206 are placed in physical communication, motor 304 may reverse direction and return nut 310 and collar 204 to the opposite end of threaded shaft 306, such as a home position. To achieve this motion, processor 330 and H-bridge 332 of controller PCB 302 are utilized. In an example, H-bridge 332 may be any suitable device that incorporates field-effect transistors (FETs) or other components to change polarity to drive motor 304 forward and reverse.

As illustrated in FIG. 1, quick disconnect component 200 may be electrical communication with a server, such as server 102 of FIG. 1, via a three-wire interface. In an example, the three-wire interface may extend from within motor housing 210, through wire connector 214, and out of quick disconnect component 200. Two of the wires may provide power to controller PCB 302 and motor 304, and the third wire may be utilized to activate quick disconnect component 200 and report the status of the quick disconnect component. In certain examples, the communication wire may be connected to a baseboard management controller (BMC) of a server, such as server 102 of FIG. 1.

When an assertion signal is received from a server, processor 330 may drive H-bridge 332 in a forward motion, which in turn causes motor 304 to pull nut 310 and collar 204 in the direction of arrow 450. At the end of the forward stroke, collar 204 may be in physical communication with collar 206 and the current drawn by motor 304 may spike. When the current hits a preset level processor 330 may reverse the polarity of H-bridge 332, and nut 310 may return to its initial position where quick disconnect component 200 may bottom out at the opposite end of threaded shaft 306. In this situation, the current may spike again indicating end of stroke to processor 330. In certain examples, these operations may be utilized as a self-test of quick disconnect component 200, to detect an attached hose, or the like.

In certain examples, the one communication wire may provide a communication interface to enable several status capabilities for operation and health of quick disconnect component 200.

In response to an initial power on of quick disconnect component 200, PCB controller 302 may control motor 304 to cause nut 310, block 308, and manifold portion 240 to a home position. This operation may ensure that a return cycle of quick disconnect component 200 is completed in case power was interrupted during activation of quick disconnect component. In response to the return cycle, controller PCB 302 may provide a device present signal to a server, such as server 102 of FIG. 1. This device present signal may indicate that quick disconnect component 200 is plugged in.

In an example, periodic tests of quick disconnect component 200 may be performed to determine whether the quick disconnect component is still operating properly. Based on H bridge 332 having a current sense, a server, such as server 102 of FIG. 1, may periodically cause motor 304 to run, but stop the motor before quick disconnect component 200 is disconnected from the manifold. In certain examples, threaded shaft 306 may include some overtravel such that the threaded shaft may free spin for a period of time before the current sense of H-bridge 332 detects the strain of actuating the disconnect. In an example, the strain may result from threaded shaft 306 pulling nut 310 and block 308 toward motor 304.

In certain examples, the test of quick disconnect component 200 may be run for a particular amount out time. During this amount of time, the current sense of H-bridge 332 may determine whether any amount of current is drawn by motor 304. In an example, if a current spike is detected or determined, processor 330 may immediately stop causing motor 304 from spinning drive shaft 412, which in turn will stop the rotation of threaded shaft 306. Processor 330 may then cause motor 304 to return nut 310 to a parked position. During the test of quick disconnect component 200, processor 330 may return the status of quick disconnect component 200 to the server over the one wire interface.

In an example, if H-bridge 332 detects a normal current with a slow increase, processor 330 may detect a normal operation of motor 304 and quick disconnect component 200. Processor 330 may determine different conditions that may indicate a failure of motor 304 and quick disconnect component 200. For example, based on H-bridge 332 detecting an instantaneous current spike, processor 330 may determine that motor 304 has seized. Based on H-bridge 332 detecting no current through motor 304, processor 330 may determine an open circuit. Based on processor 330 not receiving a response from H-bridge 332, processor 330 may determine that the drive circuit is dead.

In certain examples, the communication between processor 330 and the server may be performed in any suitable manner. For example, a weak pulldown on the server side and a strong pullup on the motor side. In an example, in response to the server writing an open drain low level on the communication wire, processor 330 may trigger a disconnect cycle. If the server reads a high voltage level on the communication wire, the server may detect a cable present. If the server reads a low voltage level, the server may detect a cable not present.

In an example, quick disconnect component 200 may be a universal serial bus (USB) device and plug to a USB port on the back of the server. In certain examples, the USB cable may supply power from the server and a fully bi-directional communication interface may enable more communication capability between the server and quick disconnect component 200. USB on the back of the server makes the interface useful for other capabilities should the customer not utilize the quick disconnect mechanism.

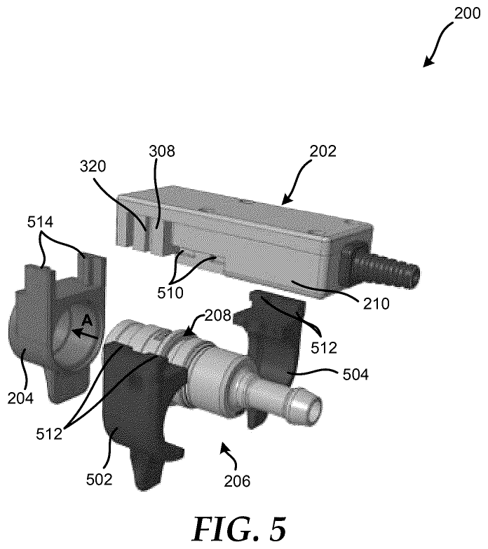

FIG. 5-7 illustrate different assembly stages of quick disconnect component 200 according to at least one embodiment of the present disclosure. Collar 206 includes portions 502 and 504. Motor assembly 202 includes notches 510 on both sides of motor housing 210. Each of portions 502 and 504 includes tabs 512. Collar 204 includes raised portions 514. Each different tab 512 corresponds to a different one of notches 510. Similarly, each different raised portion 514 corresponds to a different one of channels 320. Quick disconnect component 200 may include additional sub-components without varying from the scope of this disclosure.

Referring to FIG. 5, during the assembly of quick disconnect component 200, disconnect 208 may be inserted within an opening of collar 204 in the direction of arrow A. As disconnect 208 is inserted within collar 204, a ridge within the opening of the collar may snap fit within a channel of the disconnect. When disconnect 208 has snap fitted within collar 204, the collar and the disconnect may be securely attached to each other.

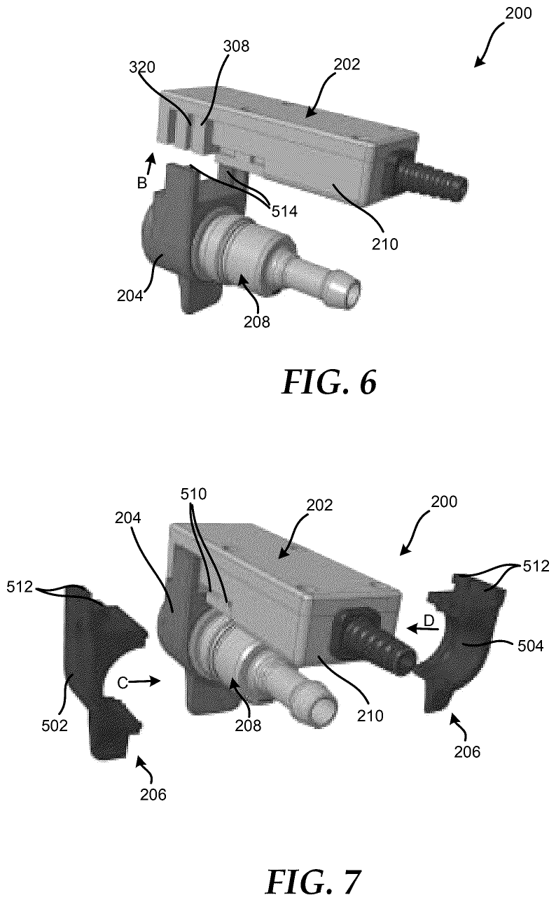

Referring to FIG. 6, after collar 204 and disconnect 208 are securely attached to each other, raised positions 514 may be aligned with channels 320 of block 308. Collar 204 and disconnect 208 may be moved toward block 308 in the direction of arrow B. As collar 204 is moved toward block 308, raised portions 514 may slide within channels 320 until the collar is in physical communication with the block.

Referring to FIG. 7, after collar 204 and disconnect 208 are securely attached block 308, portion 502 of collar 206 may be moved toward disconnect 208 in the direction of arrow C. Additionally, portion 504 may be moved toward disconnect 208 in the direction of arrow D. In an example, tabs 512 of portion 502 may snap fit within notches 510 on one side of motor housing 210, and tabs 512 of portion 504 may snap fit within notches 510 on the other side of the motor housing. In certain examples, collars 204 and 206 may securely coupled disconnect 208 to motor assembly 202 of quick disconnect component 200.

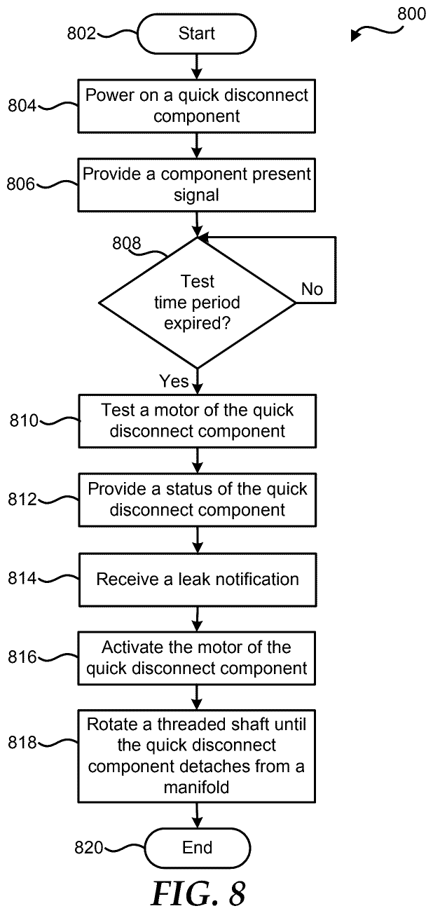

FIG. 8 is a flow diagram of a method 800 for determining a status of a quick disconnect component according to at least one embodiment of the present disclosure, starting at block 802. It will be readily appreciated that not every method step set forth in this flow diagram is always necessary, and that certain steps of the methods may be combined, performed simultaneously, in a different order, or perhaps omitted, without varying from the scope of the disclosure. FIG. 8 may be employed in whole, or in part, processor 310 in FIG. 3, or any other type of controller, device, module, processor, or any combination thereof, operable to employ all, or portions of, the method of FIG. 8.

At block 804, a quick disconnect component is powered on. In an example, the quick disconnect component may be connected within a liquid cooling system. For example, the quick disconnect component may be connected between a supply manifold and a supply line of the liquid cooling system, or between a return line and a return manifold of the liquid cooling system. At block 806, a component present signal is provided. In an example, the component present signal may be provided to an information handling system, such as a server, that is cooling by the liquid cooling system. In certain examples, the quick disconnect component may be coupled to the server via multiple wires. For example, the quick disconnect component may receive power from the server through multiple wires and may communicate with the server via a communication wire.

At block 808, a determination is made whether a test time period has expired. In response to the test time period expiring, the motor of the quick disconnect component is tested by a processor within the quick disconnect component at block 810. In an example, the test may be performed for a particular amount of time, such that the running of the motor is stopped before a disconnection of the liquid cooling line is performed. For example, the test may be performed until the current starts to climb. In certain examples, the processor may receive or detect the current in the motor from a drive circuit of the quick disconnect component, and the current may be used to determine the status of the motor. If a slow current increase is detected, the processor may determine that the motor is working properly. If an instant current spike is detected, the processor may determine that the motor has seized. If no current is detected, an open circuit is detected. If no response is received from the drive circuit, the processor may determine that the drive circuit is dead.

At block 812, a status of the motor is provided. In an example, the processor of the quick disconnect component may provide the status to the associated information handling system or server. The provided status may be one of multiple possible statuses, such as motor is operating properly, motor seized, open circuit, drive circuit is dead, or the like. These statuses may be provided in any suitable manner from the processor of the quick disconnect component to the server.

At block 814, a leak notification is received the processor of the quick disconnect component. In an example, the leak notification may be received from a server in communication with the quick disconnect component. In response to the leak notification, the motor of the quick disconnect component is activated at block 816. At block 818, a threaded shaft is rotated until the quick disconnect component detaches from a manifold and the flow ends at block 820. In an example, the motor may rotate the threaded shaft, which in turn may pull a nut and block toward the motor. When the block reaches a motor housing of the quick disconnect component, the quick disconnect component may detach from a manifold of a liquid cooling system.

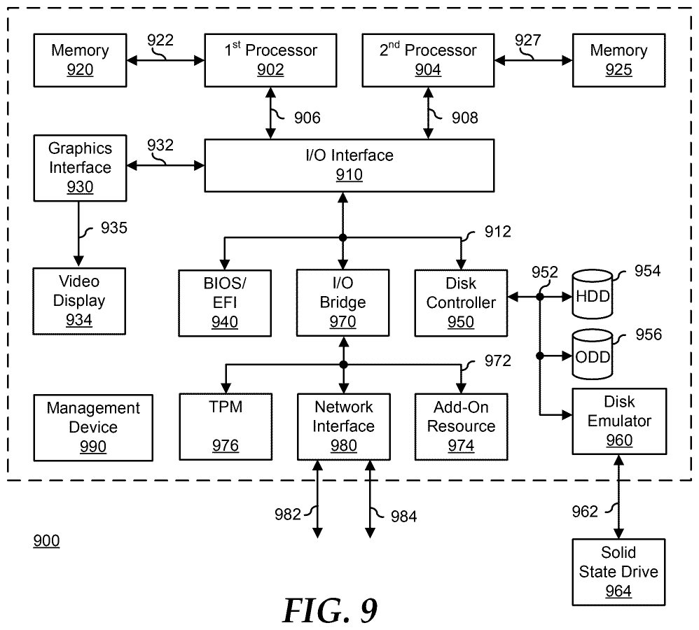

FIG. 9 shows a generalized embodiment of an information handling system 900 according to an embodiment of the present disclosure. Information handling system 900 may be substantially similar to information handling systems or servers 102 of FIG. 1. For purpose of this disclosure an information handling system can include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, information handling system 900 can be a personal computer, a laptop computer, a smart phone, a tablet device or other consumer electronic device, a network server, a network storage device, a switch router or other network communication device, or any other suitable device and may vary in size, shape, performance, functionality, and price. Further, information handling system 900 can include processing resources for executing machine-executable code, such as a central processing unit (CPU), a programmable logic array (PLA), an embedded device such as a System-on-a-Chip (SoC), or other control logic hardware.

Information handling system 900 can also include one or more computer-readable medium for storing machine-executable code, such as software or data. Additional components of information handling system 900 can include one or more storage devices that can store machine-executable code, one or more communications ports for communicating with external devices, and various input and output (I/O) devices, such as a keyboard, a mouse, and a video display. Information handling system 900 can also include one or more buses operable to transmit information between the various hardware components.

Information handling system 900 can include devices or modules that embody one or more of the devices or modules described below and operates to perform one or more of the methods described below. Information handling system 900 includes a processors 902 and 904, an input/output (I/O) interface 910, memories 920 and 925, a graphics interface 930, a basic input and output system/universal extensible firmware interface (BIOS/UEFI) module 940, a disk controller 950, a hard disk drive (HDD) 954, an optical disk drive (ODD) 956, a disk emulator 960 connected to an external solid state drive (SSD) 964, an I/O bridge 970, one or more add-on resources 974, a trusted platform module (TPM) 976, a network interface 980, a management device 990, and a power supply 995. Processors 902 and 904, I/O interface 910, memory 920, graphics interface 930, BIOS/UEFI module 940, disk controller 950, HDD 954, ODD 956, disk emulator 960, SSD 964, I/O bridge 970, add-on resources 974, TPM 976, and network interface 980 operate together to provide a host environment of information handling system 900 that operates to provide the data processing functionality of the information handling system. The host environment operates to execute machine-executable code, including platform BIOS/UEFI code, device firmware, operating system code, applications, programs, and the like, to perform the data processing tasks associated with information handling system 900.

In the host environment, processor 902 is connected to I/O interface 910 via processor interface 906, and processor 904 is connected to the I/O interface via processor interface 908. Memory 920 is connected to processor 902 via a memory interface 922. Memory 925 is connected to processor 904 via a memory interface 927. Graphics interface 930 is connected to I/O interface 910 via a graphics interface 932 and provides a video display output 936 to a video display 934. In a particular embodiment, information handling system 900 includes separate memories that are dedicated to each of processors 902 and 904 via separate memory interfaces. An example of memories 920 and 930 include random access memory (RAM) such as static RAM (SRAM), dynamic RAM (DRAM), non-volatile RAM (NV-RAM), or the like, read only memory (ROM), another type of memory, or a combination thereof.

BIOS/UEFI module 940, disk controller 950, and I/O bridge 970 are connected to I/O interface 910 via an I/O channel 912. An example of I/O channel 912 includes a Peripheral Component Interconnect (PCI) interface, a PCI-Extended (PCI-X) interface, a high-speed PCI-Express (PCIe) interface, another industry standard or proprietary communication interface, or a combination thereof. I/O interface 910 can also include one or more other I/O interfaces, including an Industry Standard Architecture (ISA) interface, a Small Computer Serial Interface (SCSI) interface, an Inter-Integrated Circuit (I²C) interface, a System Packet Interface (SPI), a Universal Serial Bus (USB), another interface, or a combination thereof. BIOS/UEFI module 940 includes BIOS/UEFI code operable to detect resources within information handling system 900, to provide drivers for the resources, initialize the resources, and access the resources. BIOS/UEFI module 940 includes code that operates to detect resources within information handling system 900, to provide drivers for the resources, to initialize the resources, and to access the resources.

Disk controller 950 includes a disk interface 952 that connects the disk controller to HDD 954, to ODD 956, and to disk emulator 960. An example of disk interface 952 includes an Integrated Drive Electronics (IDE) interface, an Advanced Technology Attachment (ATA) such as a parallel ATA (PATA) interface or a serial ATA (SATA) interface, a SCSI interface, a USB interface, a proprietary interface, or a combination thereof. Disk emulator 960 permits SSD 964 to be connected to information handling system 900 via an external interface 962. An example of external interface 962 includes a USB interface, an IEEE 4394 (Firewire) interface, a proprietary interface, or a combination thereof. Alternatively, solid-state drive 964 can be disposed within information handling system 900.

I/O bridge 970 includes a peripheral interface 972 that connects the I/O bridge to add-on resource 974, to TPM 976, and to network interface 980. Peripheral interface 972 can be the same type of interface as I/O channel 912 or can be a different type of interface. As such, I/O bridge 970 extends the capacity of I/O channel 912 when peripheral interface 972 and the I/O channel are of the same type, and the I/O bridge translates information from a format suitable to the I/O channel to a format suitable to the peripheral channel 972 when they are of a different type. Add-on resource 974 can include a data storage system, an additional graphics interface, a network interface card (NIC), a sound/video processing card, another add-on resource, or a combination thereof. Add-on resource 974 can be on a main circuit board, on separate circuit board or add-in card disposed within information handling system 900, a device that is external to the information handling system, or a combination thereof.

Network interface 980 represents a NIC disposed within information handling system 900, on a main circuit board of the information handling system, integrated onto another component such as I/O interface 910, in another suitable location, or a combination thereof.

Network interface device 980 includes network channels 982 and 984 that provide interfaces to devices that are external to information handling system 900. In a particular embodiment, network channels 982 and 984 are of a different type than peripheral channel 972 and network interface 980 translates information from a format suitable to the peripheral channel to a format suitable to external devices. An example of network channels 982 and 984 includes InfiniBand channels, Fibre Channel channels, Gigabit Ethernet channels, proprietary channel architectures, or a combination thereof. Network channels 982 and 984 can be connected to external network resources (not illustrated). The network resource can include another information handling system, a data storage system, another network, a grid management system, another suitable resource, or a combination thereof.

Management device 990 represents one or more processing devices, such as a dedicated baseboard management controller (BMC) System-on-a-Chip (SoC) device, one or more associated memory devices, one or more network interface devices, a complex programmable logic device (CPLD), and the like, which operate together to provide the management environment for information handling system 900. In particular, management device 990 is connected to various components of the host environment via various internal communication interfaces, such as a Low Pin Count (LPC) interface, an Inter-Integrated-Circuit (I2C) interface, a PCIe interface, or the like, to provide an out-of-band (OOB) mechanism to retrieve information related to the operation of the host environment, to provide BIOS/UEFI or system firmware updates, to manage non-processing components of information handling system 900, such as system cooling fans and power supplies. Management device 990 can include a network connection to an external management system, and the management device can communicate with the management system to report status information for information handling system 900, to receive BIOS/UEFI or system firmware updates, or to perform other task for managing and controlling the operation of information handling system 900.

Management device 990 can operate off of a separate power plane from the components of the host environment so that the management device receives power to manage information handling system 900 when the information handling system is otherwise shut down. An example of management device 990 include a commercially available BMC product or other device that operates in accordance with an Intelligent Platform Management Initiative (IPMI) specification, a Web Services Management (WSMan) interface, a Redfish Application Programming Interface (API), another Distributed Management Task Force (DMTF), or other management standard, and can include an Integrated Dell Remote Access Controller (iDRAC), an Embedded Controller (EC), or the like. Management device 990 may further include associated memory devices, logic devices, security devices, or the like, as needed, or desired.

Although only a few exemplary embodiments have been described in detail herein, those skilled in the art will readily appreciate that many modifications are possible in the exemplary embodiments without materially departing from the novel teachings and advantages of the embodiments of the present disclosure. Accordingly, all such modifications are intended to be included within the scope of the embodiments of the present disclosure as defined in the following claims. In the claims, means-plus-function clauses are intended to cover the structures described herein as performing the recited function and not only structural equivalents, but also equivalent structures.

What is claimed is:

1. A quick disconnect component comprising:
a disconnect including a manifold portion and a hose portion; and
a motor assembly coupled to the disconnect, the motor assembly including a motor, wherein in response to a leak indication the motor to pull the manifold portion towards the hose portion, and when the manifold portion is in physical communication with the hose portion the disconnect to automatically detach from a manifold of a liquid cooling system in an information handling system.

2. The quick disconnect component of claim 1, wherein the motor assembly further includes a controller printed circuit board, the controller printed circuit board includes a processor and a H-bridge, wherein the processor and the H-bridge control an operation of the motor.

3. The quick disconnect component of claim 2, wherein the processor and the H-bridge periodically test the motor.

4. The quick disconnect component of claim 1, wherein the motor assembly further includes a threaded shaft connected to the motor, a nut connected on the threaded shaft, and a block in physical communication with the nut and with the threaded shaft, wherein movement of the block causes a corresponding movement of the manifold portion.

5. The quick disconnect component of claim 1, further comprising a first collar secured to the manifold portion, and a second collar secured to the hose portion.

6. The quick disconnect component of claim 5, wherein an external force on the first collar pushes the first collar and the manifold portion toward the second collar and the hose portion, wherein the external force is provided from outside of the quick disconnect component.

7. The quick disconnect component of claim 6, when the external force is removed the first collar and the manifold portion slides away from the second collar and the hose portion.

8. A system comprising:
an information handling system;
a liquid cooling supply manifold to supply a cooling liquid to the information handling system; and
a quick disconnect component coupled to the liquid cooling supply manifold, the liquid cooling supply manifold including:
a disconnect including a manifold portion and a hose portion; and
a motor assembly coupled to the disconnect and including a motor, wherein in response to a leak indication the motor pulls the manifold portion towards the hose portion, and when the manifold portion is in physical communication with the hose portion the disconnect automatically detaches from a manifold of a liquid cooling system in the information handling system.

9. The system of claim 8, wherein the motor assembly further includes a controller printed circuit board, the controller printed circuit board includes a processor and a H-bridge, wherein the processor and the H-bridge control an operation of the motor.

10. The system of claim 9, wherein the processor and the H-bridge periodically test the motor.

11. The system of claim 8, wherein the motor assembly further includes a threaded shaft connected to the motor, a nut connected on the threaded shaft, and a block in physical communication with the nut and with the threaded shaft, wherein movement of the block causes a corresponding movement of the manifold portion.

12. The system of claim 8, wherein the quick disconnect component further includes: a first collar secured to the manifold portion, and a second collar secured to the hose portion.

13. The system of claim 12, wherein an external force on the first collar pushes the first collar and the manifold portion toward the second collar and the hose portion, wherein the external force is provided from outside of the quick disconnect component.

14. The system of claim 13, when the external force is removed the first collar and the manifold portion slides away from the second collar and the hose portion.

15. A system comprising:
an information handling system;
a liquid cooling supply manifold to supply a cooling liquid to the information handling system;
a return manifold to receive hot liquid from the information handling system;
a check value coupled between the information handling system and the return manifold; and
a quick disconnect component coupled to the liquid cooling supply manifold, the liquid cooling supply manifold including:
a disconnect including a manifold portion and a hose portion; and
a motor assembly coupled to the disconnect, the motor assembly including a motor, wherein in response to a leak indication the motor is adapted to pull the manifold portion towards the hose portion, and when the manifold portion is in physical communication with the hose portion the disconnect is adapted to automatically detach from a manifold of a liquid cooling system in the information handling system.

16. The system of claim 15, wherein the motor assembly further includes a controller printed circuit board, the controller printed circuit board includes a processor and a H-bridge, wherein the processor and the H-bridge control an operation of the motor.

17. The system of claim 15, wherein the motor assembly further includes a threaded shaft connected to the motor, a nut connected on the threaded shaft, and a block in physical communication with the nut and with the threaded shaft, wherein movement of the block causes a corresponding movement of the manifold portion.

18. The system of claim 15, wherein the quick disconnect component further includes: a first collar secured to the manifold portion, and a second collar secured to the hose portion.

19. The system of claim 18, wherein an external force on the first collar pushes the first collar and the manifold portion toward the second collar and the hose portion, wherein the external force is provided from outside of the quick disconnect component.

20. The system of claim 19, when the external force is removed the first collar and the manifold portion slides away from the second collar and the hose portion.
